(19) United States
(12) Patent Application Publication
(10) Pub. No.: US 2017/0004995 A1
(43) Pub. Date: Jan. 5, 2017

(54) Film Forming Apparatus and Film Forming Method

(71) Applicant: ULVAC, INC., Kanagawa (JP)

(72) Inventors: Keiichiro Asakawa, Kanagawa (JP); Junichi Hamaguchi, Kanagawa (JP); Kazuhiro Sonoda, Kanagawa (JP); Yukinobu Numata, Kanagawa (JP); Yutaka Kokaze, Kanagawa (JP)

(73) Assignee: ULVAC, INC., Kanagawa (JP)

(21) Appl. No.: 15/125,726

(22) PCT Filed: Feb. 24, 2016
(86) PCT No.: PCT/JP2016/000989

§ 371 Date: Sep. 13, 2016

(30) Foreign Application Priority Data
Feb. 25, 2015 (JP) 2015-034740

(51) Int. Cl. H01L 21/768; C23C 14/18; C23C 14/34; H01J 37/32; H01J 37/34

(52) U.S. Cl. CPC H01L 21/76867; H01L 21/76865; H01J 37/32036; H01J 37/3476; C23C 14/3407; H01J 37/3426; C23C 14/185; H01J 2237/334

(57) ABSTRACT

Provided is a film forming apparatus in which a thin film can be formed with a good coverage on the inner surface of a hole with high aspect ratio by preventing the negative electric charges from getting concentrated on the substrate edge portion at the time of etching processing. The film forming apparatus is provided with: a vacuum chamber in which a target is disposed; a stage for holding a substrate inside the vacuum chamber; a first electric power for applying predetermined electric power to the target; and a second electric power for applying AC power to the stage. The film forming apparatus performs: film forming processing in which the target is sputtered by applying electric power to the target by the first electric power; and etching processing in which a thin film formed on the substrate is etched by applying AC power to the stage by the second electric power.

### TECHNICAL FIELD

The present invention relates to a film forming apparatus and a film forming method and, in particular, relates to an apparatus and a method which are suitable for forming thin films, with a better coverage, on inner surfaces of micro-holes having high aspect ratios.

### BACKGROUND ART

In the semiconductor manufacturing steps there is a step of forming a barrier layer constituted by a Ta film on the inside surfaces (inside wall surface and bottom surface) of a via hole or a contact hole having a predetermined aspect ratio. As a result of recent high integration and micro-structuring of semiconductor devices, some holes in which Ta films are formed have high aspect ratios of 3 or more. As a film forming apparatus to be used in film formation of this kind of Ta films, there is known one, e.g., in Patent Document 1. The apparatus in question is made up of: a vacuum chamber in which a target is disposed; a stage for holding a substrate inside the vacuum chamber; a first power source for applying a predetermined electric power to the target; and a second power source for applying AC power to the stage. The apparatus is capable of performing: film forming processing in which the target is sputtered by applying electric power by the first power source to the target; and etching processing in which a thin film formed on the substrate is etched by applying AC power by the second power source to the stage. According to this arrangement, Ta films formed thick on the surface of the substrate and on the bottom of the holes by the film forming processing are etched, and the etched Ta particles get adhered to the inner wall surfaces of the holes having thinner film thicknesses, thereby improving the coverage.

By the way, at the time of film forming processing, in order to prevent the sputtered particles from getting adhered, at the time of film forming processing, to the inner wall surface of the vacuum chamber and to the component parts present inside the vacuum chamber, there is disposed inside the vacuum chamber a deposition prevention plate in a manner to enclose the space between the target and the substrate. Then that portion of the deposition prevention plate which is disposed around the stage is normally arranged to be proximate to the substrate on the same plane as the upper surface of the substrate in order to prevent the sputtered particles from turning around into the space below the stage through the clearance between the said portion and the substrate. However, it has been found that, when the etching processing is performed in a state in which the deposition prevention plate is disposed in a manner as described, in-plane distribution of the etching rate will be deteriorated and therefore that the coverage cannot be sufficiently improved. After strenuous studies and efforts, the inventors of this invention have obtained a finding that the deterioration of in-plane distribution of etching rate is attributable to the phenomenon that the negative electric charges accumulated in the substrate will be attracted toward that portion of the deposition prevention plate which is proximate to the substrate, thereby concentrating on the edge portion of the substrate.

### PRIOR ART DOCUMENTS

### Patent Documents

Patent Document 1: JP-T-2013-538295

### SUMMARY OF INVENTION

### Problems to be Solved by the Invention

This invention has a problem of providing a film forming apparatus and a film forming method in which, based on the above-mentioned finding, by preventing the negative electric charges from concentrating on the edge portion of the substrate at the time of etching processing, a thin film can be formed at good coverage on the inner surfaces of holes of high aspect ratio.

### Means For Solving the Problems

In order to solve the above-mentioned problems, this invention is a film forming apparatus comprising: a vacuum chamber in which a target is disposed; a stage for holding a substrate inside the vacuum chamber; a first power source for applying a predetermined electric power to the target; a second power source for applying AC power to the stage, thereby performing: film forming processing in which the target is sputtered by applying electric power by the first power source to the target; and etching processing in which a thin film formed on the substrate is etched by applying AC power by the second power source to the stage. The film forming apparatus is characterized in that a deposition prevention plate which encloses the stage is disposed. Let that side of the substrate held in position by the stage which is subjected to film forming be defined as an upper side. The film forming apparatus further comprises a driving means for moving up and down the deposition prevention plate between a film forming position in which that portion of the deposition prevention plate which is proximate to the substrate is positioned on a plane substantially equal to an upper surface of the substrate, and an etching position in which the said portion of the deposition prevention plate is positioned above the upper surface of the substrate.

According to this invention, at the time of etching after the film forming processing, the deposition prevention plate is moved by the driving means to the etching position. As a result, that portion of the deposition prevention plate which is proximate to the substrate is away from the substrate. Therefore, the negative electric charges can be prevented from concentrating on the edge portion of the substrate, and the in-plane distribution of the etching rate can be improved. Therefore, if this invention is applied to the case in which a thin film is formed inside a hole of high aspect ratio, the thin film can be formed on the inner surface of the hole at good coverage.

In this invention, preferably, a projected strip elongated downward is disposed in that portion of the deposition prevention plate which is proximate to the substrate. According to this arrangement, the particles scattered from the thin film at the time of etching get adhered to the projected strip. Therefore, it is possible to prevent the scattered particles from getting adhered to an inner surface of the vacuum chamber as a result of passing through the clearance between that portion of the deposition prevention plate which is proximate to the substrate and the substrate. In this case, the height of the projected strip may be set to be equal to or above a distance between the film forming position and the etching position, e.g., within a range of 10˜30 mm.

In this invention, instead of providing a projected strip, the film forming apparatus may alternatively further comprises: a second deposition prevention plate disposed below the deposition prevention plate; and a second driving means for moving up and down the second deposition prevention plate between a film forming position in which an upper end portion of the second deposition prevention plate is positioned below the substrate, and the etching position in which the upper end portion of the second deposition prevention plate, that has been moved to the etching position, is proximate to the substrate. According to this arrangement, by moving the deposition prevention plate to the etching position and also by moving the second deposition prevention plate to the etching position, the particles scattered from the thin film at the time of etching processing can be made to get adhered to the second deposition prevention plate. The scattered particles can thus be prevented from passing through the clearance between that portion of the deposition prevention plate which is proximate to the substrate and the substrate so as to get adhered to the inner surface of the vacuum chamber.

In this invention, preferably, the vacuum chamber comprises a pair of upper and lower coils, and wherein the pair of upper and lower coils are positioned relative to the vacuum chamber so as to sandwich, in the vertical direction, plasma generated when AC power is applied to the stage by the second power source. Then, the in-plane uniformity of the etching rate can be further improved so that the coverage can further be improved.

Further, in order to solve the above-mentioned problems, the film forming method according to this invention comprises: a film forming step in which a substrate is held by a stage in a vacuum chamber, a deposition prevention plate is disposed so as to enclose the stage, and a predetermined electric power is applied to a target in the vacuum chamber to thereby perform sputtering; and an etching step in which the electric power application to the target is stopped, and AC power is applied to the stage to thereby etch a thin film formed on the substrate. Let that side of the substrate held by the stage which is the film-forming side be defined as an upper side. In the film forming step, the deposition prevention plate is moved to a film forming position in which that portion of the deposition prevention plate which is proximate to the substrate is positioned on a plane substantially equal to an upper surface of the substrate. In the etching step, the deposition prevention plate is moved to an etching position which is different from the film forming position and in which the said portion of the deposition prevention plate is positioned above the upper surface of the substrate.

In this invention, the etching position is preferably positioned 10˜30 mm above the film forming position.

Preferably, in the film forming step, a second deposition prevention plate is disposed below the upper surface of the substrate, in the etching step, the second deposition prevention plate is moved upward so that the particles scattered from the thin film can be prevented from passing through a clearance between that portion of the deposition prevention plate which is proximate to the substrate and the substrate, to thereby adhere to an inner surface of the vacuum chamber.

### BRIEF DESCRIPTION OF DRAWINGS

FIG. 1 is a schematic sectional view showing a sputtering apparatus according to an embodiment of this invention.

FIG. 2A is a schematic view showing the film forming position of the deposition prevention plate, FIG. 2B is one showing the etching position of the deposition prevention plate, and FIG. 2C is one showing the transferring position of the deposition prevention plate, respectively.

FIG. 3A is a schematic view explaining the film forming processing, and FIG. 3B is one explaining the etching processing, respectively.

FIG. 4 is a schematic sectional view showing a modified example of the sputtering apparatus of this invention.

FIG. 5 is a graph showing the results of experiment to confirm the effects of this invention.

FIG. 6 is a graph showing the results of experiment to confirm the effects of this invention.

### EMBODIMENTS TO CARRY OUT THE INVENTION

With reference to the accompanying drawings, description will hereinafter be made of a film forming apparatus according to an embodiment of this invention by taking an example of a sputtering apparatus which is used in forming a substrate W to be processed by forming an insulating film L on a surface of a silicon wafer SW to a predetermined thickness. Microstructural holes h having an aspect ratio of 3 or more are formed in the insulating film L. On the inside of the respective holes h a barrier layer constituted by a Ta film f is formed.

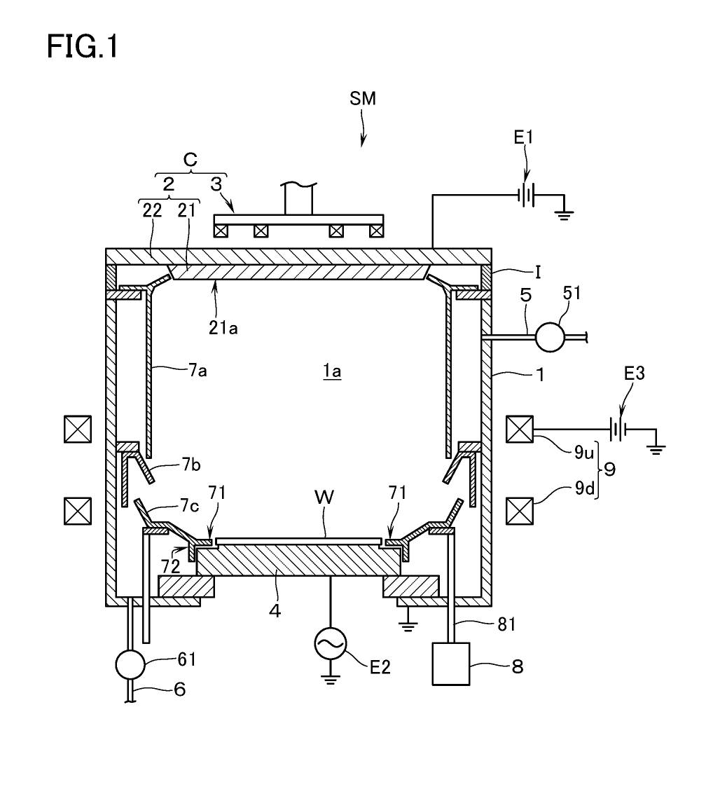

With reference to FIG. 1, reference characters SM denote a sputtering apparatus of a magnetron system. This sputtering apparatus SM is provided with a vacuum chamber 1 which defines a processing chamber 1a. On a ceiling portion of the vacuum chamber 1 there is mounted a cathode unit C. In the following description, explanation is made on condition that the direction looking toward the ceiling portion of the vacuum chamber 1 in FIG. 1 is defined as the “upper side” and the direction looking toward the bottom side thereof is defined as the “lower side.”

The cathode unit C is constituted by a target assembly 2 and a magnet unit 3 which is disposed above the target assembly 2. Depending on the profile of the substrate W, the target assembly 2 is constituted by: a target 21 which is formed, by a known method, of Tantalum (Ta) into a shape of a circular plate as seen in plan view (i.e., as seen from top downward); and a backing plate 22 which is bonded to an upper surface of the target 21 by means of a bonding agent (not illustrated) such as indium and the like. It is so arranged that, during film forming by sputtering, the target 21 can be cooled by circulating a cooling medium (cooling water) through the inside of the backing plate 22. In a state in which the target 21 has been mounted in position, the peripheral portion of the lower surface of the backing plate 22 is fixed to an upper portion of the side wall of the vacuum chamber 1 through an electrically insulating body 1. The target 21 has connected thereto an output from a first power source E1 such as a DC power source, RF power source and the like so that, at the time of film-forming processing, electric power having a negative electric potential is applied to the target 21.

The magnet unit 3 has a known construction in that: a magnetic field is generated in a slower space of the sputtering surface 21a of the target 21 and that; the electrons and the like that are ionized below the sputtering surface 21a at the time of sputtering are collected to thereby efficiently ionize the sputtered particles that are scattered from the target 21. Therefore, detailed explanation thereof is omitted here.

At the bottom portion of the vacuum chamber 1 there is disposed a stage 4 in a manner to lie opposite to the sputtering surface 21a of the target 21, and it is so arranged that the substrate W is held in position with the film-forming surface lying on the upper side. In this case, the distance between the target 21 and the substrate W is set to be within a range of 300˜600 mm in view of the productivity, scattering times, and the like. The stage 4 has connected thereto an output from a second power source E2 such as a RF power source and the like so that, at the time of etching processing, AC power is applied to the stage 4. At the time of film forming processing, AC power may be applied from the second power source E2 to the stage 4.

The side wall of the vacuum chamber 1 has connected thereto a gas pipe 5 for introducing a rare gas such as argon and the like which serves as the sputtering gas and the etching gas. The gas pipe 5, which has interposed therein a mass-flow controller 51, is in communication with a gas source (not illustrated). According to this arrangement, the flow-controlled sputtering gas or etching gas can be introduced, by evacuating means 61 which is described hereinafter, into the processing chamber 1a which is evacuated at a constant evacuating speed. It is thus so arranged that the pressure (total pressure) inside the processing chamber 1a can be held substantially constant during the film-forming processing or the etching processing. To the bottom of the vacuum chamber 1 there is connected an exhaust pipe 6 which is in communication with vacuum exhausting means 61 which is made up of a turbo molecular pump, a rotary pump, and the like.

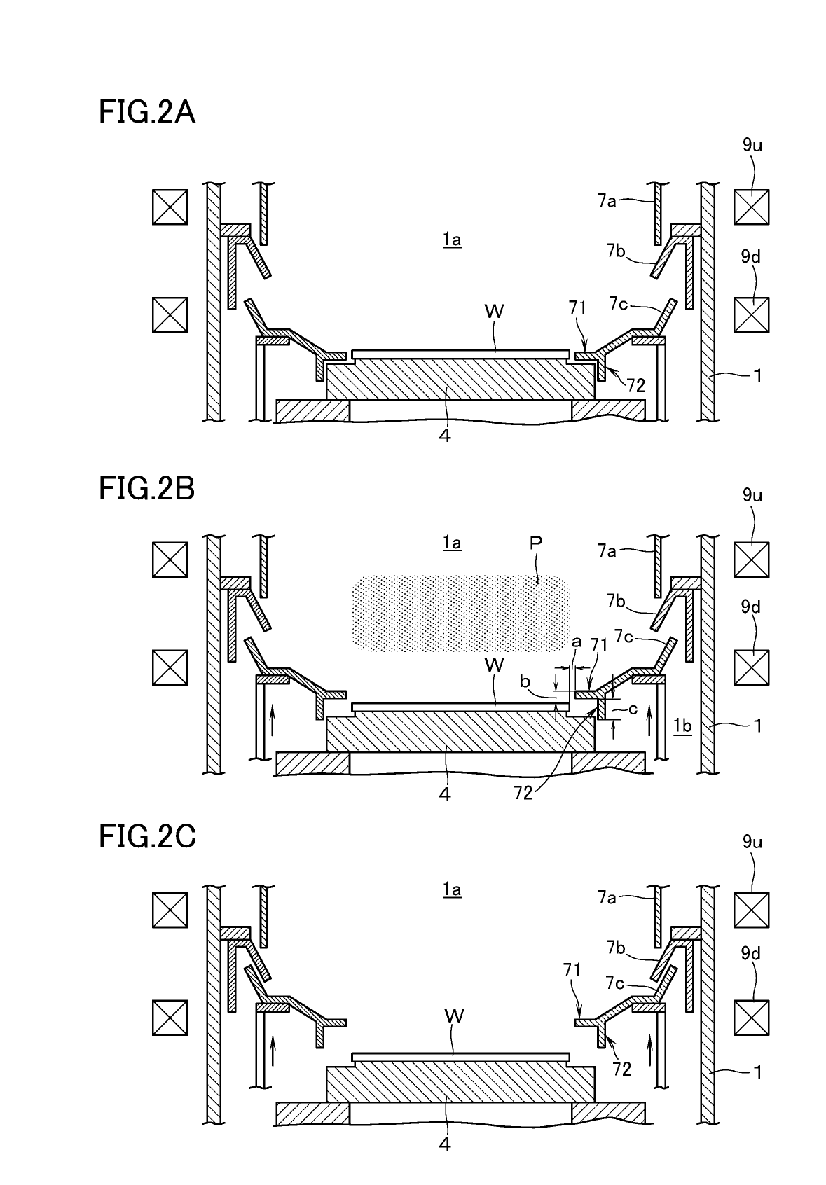

Inside the vacuum chamber 1 there are disposed deposition prevention plates 7a, 7b, 7c in a manner to enclose the space between the target 21 and the substrate W, thereby preventing the sputtered particles from getting adhered to the inner wall of the vacuum chamber 1 and to the parts present in the vacuum chamber 1. The deposition prevention plates 7c that encloses the periphery of the vacuum chamber 1 has connected thereto that driving shaft 81 of a driving means 8 which passes through the bottom plate of the vacuum chamber 1 through a sealing means (not illustrated). As the driving means 8 there may be used one having a known construction such as an air cylinder and the like. Therefore, its detailed explanation is omitted here. By driving the driving shaft 81 the deposition prevention plates 7c can be moved up and down between a film forming position as shown in FIG. 2A and an etching position as shown in FIG. 2B. At the film forming position, that portion 71 of the deposition prevention plates 7c which is proximate to the substrate W (=such a portion 71 of the deposition prevention plates 7c as is adjacent to the substrate W) is positioned on a plane equivalent to the upper surface of the substrate W. It is thus so arranged that, at the time of film forming processing, the sputtered particles do not turn around into the opposite side through the clearance between the above-mentioned portion 71 and the substrate W. At the etching position, that portion 71 of the deposition prevention plate 7c is positioned above the plane equivalent to the upper surface of the substrate W. In case etching is performed at this etching position, the etched particles (the particles to be scattered from the thin film) may turn around, through the clearance between that portion 71 and the substrate W, into the space 1b so that they may get adhered to the inner surface of the vacuum chamber 1c. In this embodiment, by providing the said portion 71 of the deposition prevention plates 7c with a projected strip 72 which is elongated downward, the above-mentioned particles can be caused to be adhered to this projected strip 72. As a result, the particles can be prevented from turning around into the space 1b, thereby preventing the particles from getting adhered to the inner surface of the vacuum chamber 1. Preferably, the distance “a” in the horizontal direction between the portion 71 of the deposition prevention plates 7c at the etching position and the substrate W is set to be within a range of 5˜10 mm, and the distance “b” in the vertical direction is set to be within a range of 10˜30 mm. By setting the respective distances to the above-mentioned ranges, at the time of etching processing, the negative electric charges accumulated in the substrate W can be prevented from getting attracted toward the above-mentioned portion 71. Further, by setting the height “c” of the projected strip 72 to be equal to or above the distance between the film forming position and the etching position (e.g., within a range of 10˜30 mm), the etched particles can surely be prevented from going into the space 1b. By the way, the driving means 8 can move, at the time of transferring at which the substrate W is transferred to the stage 4, the deposition prevention plates 7c can be moved to the transfer position as shown in FIG. 2C. At this transfer position the portion 71 of the deposition prevention plate 7c is positioned still further above the etching position.

Further, the vacuum chamber 1 is provided with a pair of upper and lower coils 9u, 9d. The coil 9 has connected thereto an output from the power source E3. When electric power is applied to the coil 9, it becomes possible to generate an upward magnetic field inside the vacuum chamber 1. As shown in FIG. 2B, the coils 9u, 9d are positioned relative to the vacuum chamber 1 so as to sandwich in the vertical direction the plasma that is generated when AC power is applied to the stage 4.

Although not particularly illustrated, the sputtering apparatus SM has a known control means which is provided with a microcomputer, sequencer, and the like. It is so arranged that the controller performs an overall control of the operation of the electric powers E1, E2, E3, the operation of the mass-flow controller 51, the operation of the vacuum exhaust means 61, the operation of the driving means 8 and the like. Description will hereinbelow be made of a film forming method for forming a Ta film f on the inside surface of the hole h in the substrate W.

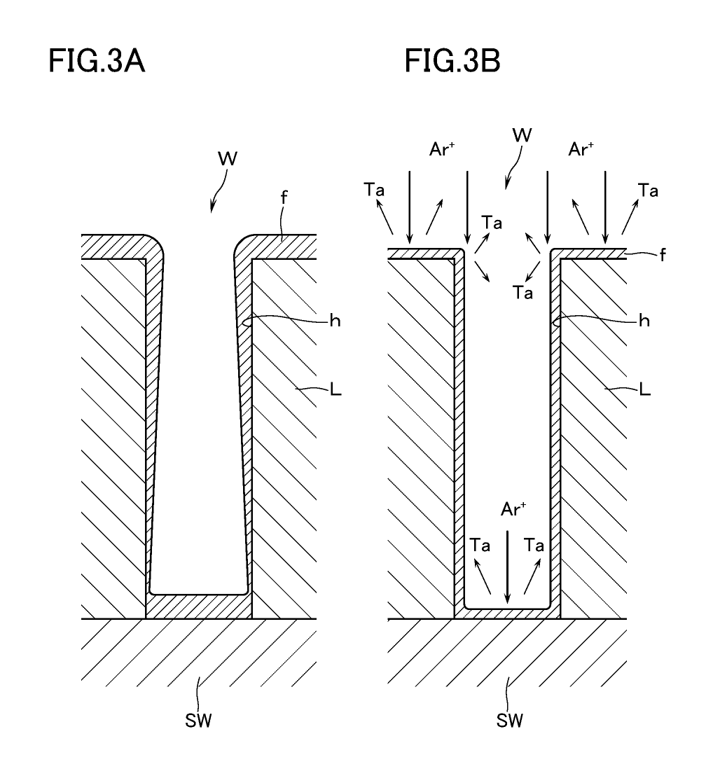

First, the driving means 8 is driven to move up the deposition prevention plates 7c to the transfer position as shown in FIG. 2C. Then, the substrate W is set in position on the stage 4 inside the vacuum chamber 1. The evacuating means 61 is operated to evacuate the vacuum chamber 1a to a predetermined vacuum degree (e.g., 1×10⁻⁵Pa). Also, the driving means 8 is driven to lower the deposition prevention plates 7c to the film forming position as shown in FIG. 2A. When the vacuum chamber 1a has reached a predetermined pressure, the mass-flow controller 51 is controlled so as to introduce argon gas at a predetermined flow rate (e.g., 5˜100 sccm) (at this time, the pressure inside the processing chamber 1a becomes a range of 0.04˜0.8 Pa). Together with the above-mentioned operations, electric power from the first power source E1 to the target 21 is applied, e.g., at 10˜25 kW to thereby form plasma inside the vacuum chamber 1. According to these operations, the sputtering surface 21a of the target 21 is sputtered, and the sputtered particles that have been scattered are caused to be adhered to the surface of the substrate W and get accumulated (or deposited) thereon, whereby a Ta film f is formed. At this time, as shown in FIG. 3A, the film thickness of the Ta film f that was formed on the surface of the substrate W (on the upper surface of the insulating film L) or at the bottom surface of the hole h becomes thicker than the film thickness of the Ta film f that was formed on the inner wall surface of the hole h.

After a lapse of a predetermined time from the start of the film forming processing, the electric power application from the first power source E1 is stopped. The driving means 8 is driven to move up the deposition prevention plates 7c to the etching position as shown in FIG. 2B. Together with this operation, AC power of 13.56 MHz from the second power source E2 is applied at 600—1200 W, thereby forming plasma. The flow amount of argon gas can be set, e.g., to 50˜100 sccm (at this time, the pressure inside the processing chamber 1a becomes a range of 0.4˜0.8 Pa).

According to this arrangement, as shown in FIG. 3B, the Ta film f of thicker film thickness will be etched and the etched Ta particles will get adhered once again to the inside wall surface of the hole h having thinner film thickness.

Here, in order to form the Ta film f with good coverage on the inside surface of the hole h, how the in-plane uniformity in etching rate can be enhanced is important. According to this embodiment, after the film forming processing and prior to the etching processing, the deposition prevention plate 7c is moved to the etching position which is higher in position than the film forming position to thereby separate the portion 71 of the deposition prevention plate 7c away from the substrate W. Therefore, at the time of etching processing, the negative charges can be prevented from being concentrated on the edge portion of the substrate W. It is therefore possible to improve the in-plane distribution of the etching rate. According to this arrangement, Ta film f of high aspect ratio can be formed on the inside of the hole h with good coverage.

Description has so far been made of an embodiment of this invention, but this invention shall not be limited to the above. In the above-mentioned embodiment, at the time of etching processing, electric power is not applied to coils 9u, 9d, but electric power may be applied to the coils 9u, 9d at the time of etching processing. According to this arrangement, as compared with the case in which electric power is not applied to the coils 9u, 9d, the in-plane uniformity of the etching rate can advantageously be improved.

Further, in the above-mentioned embodiment, description has been made of an example in which Ta film f is formed on the inside surface of the hole h, but this invention can widely be used in forming a thin film made of a metal or metallic compounds, other than Ta film.

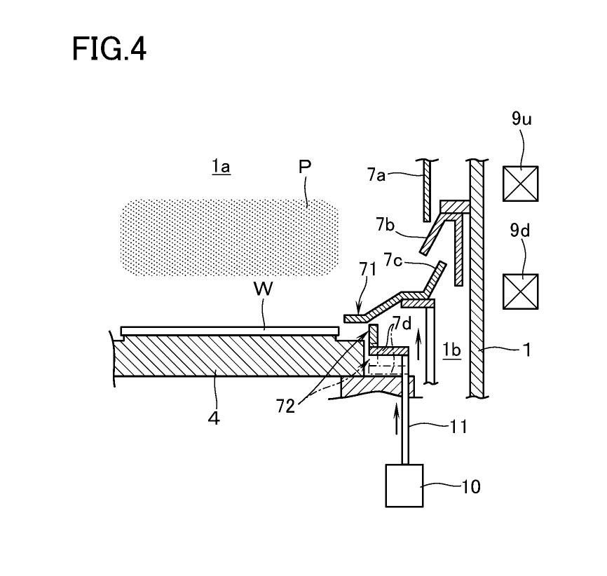

Still furthermore, in the above-mentioned embodiment, there is disposed a projected strip 72 at that portion 71 of the deposition prevention plate 7c which is proximate to the substrate W, but the projected strip may be constituted by another member. For example, as shown in FIG. 4, a further deposition prevention plate 7d is disposed below the deposition prevention plate 7c. A driving shaft 11 of a second driving means 10 is connected to this deposition prevention plate 7d so that, by driving the driving shaft 11, the deposition prevention plate 7d can be moved up and down between the etching position as shown by a solid line in the figure and the film forming position (and transfer position) as shown by a dashed line in the figure. By transferring the deposition prevention plate 7d to the etching position, the etched particles can be prevented from turning around into the space 1b through the space between the portion 71 and the substrate W and, as a result, get adhered to the inner surface of the vacuum chamber 1.

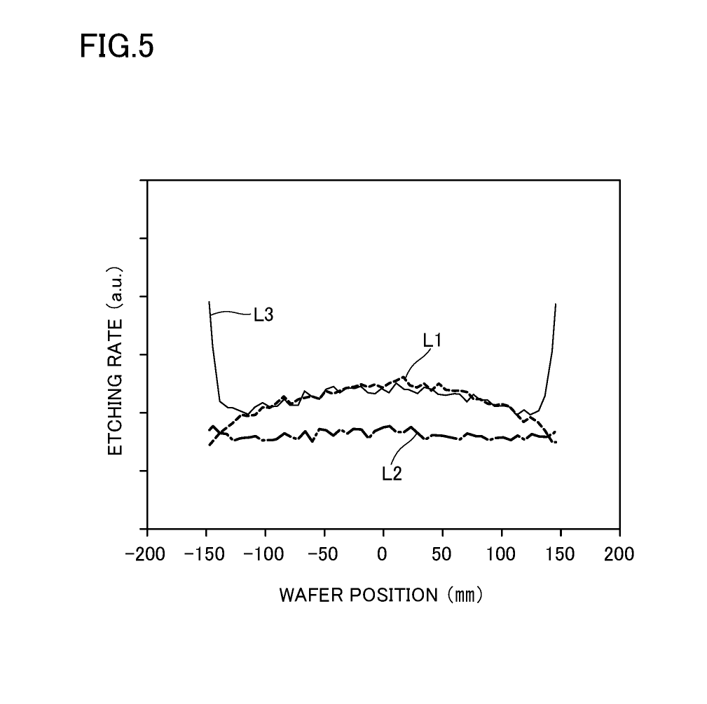

Next, in order to confirm the above-mentioned effects, the following experiments were carried out using the above-mentioned sputtering apparatus. In these experiments, as the substrate W, there was used one in which a Ta film of 50 nm thick was formed on the surface of the Si substrate of φ 300 mm with a thermal oxidation film. After having set in position the substrate W on the stage 4 inside the vacuum chamber 1, the deposition prevention plate 7c was moved to the etching position to thereby etch the Ta film. At the etching position, the distance “a” shown in FIG. 2B was set to 5 mm, and the distance b was set to 18 mm. The etching conditions at this time were as follows, namely, the flow rate of the etching gas (argon gas) was set to be 90 sccm (at this time the pressure inside the processing chamber 1a was about 0.7 Pa), and the electric power to be applied to the stage 4 was set to 13.56 MHz, 1200 W, and the electric power applied to the coil 9 was zero (electric current 0 A). The results of measurements of the etching rate at this time were shown in dashed line L1 in FIG. 5. FIG. 5 also contains the results of having etched on the same conditions as the above except that the coil 9 was applied with electric current of 15 A, the results being shown in long dashed short dashed line L2. Except for the point that the deposition prevention plate 7c was positioned in the film forming position, the result at the time of etching performed on the same conditions as above was shown in solid line L3 as the conventional example. According to this arrangement, when etching was performed while the deposition prevention plate 7c was positioned at the film forming position like in the conventional example, it was confirmed that the etching rate at the edge portion of the substrate became high. However, when the deposition prevention plate 7c was moved to the etching position, the etching rate at the edge portion of the substrate was suppressed as shown by dashed line L1 so that the in-plane uniformity was improved. Further, when the coil 9 was applied with electric power, the etching rate in the central portion of the substrate lowered as shown by long dashed short dashed line L2. It was thus confirmed that the in-plane uniformity was further improved.

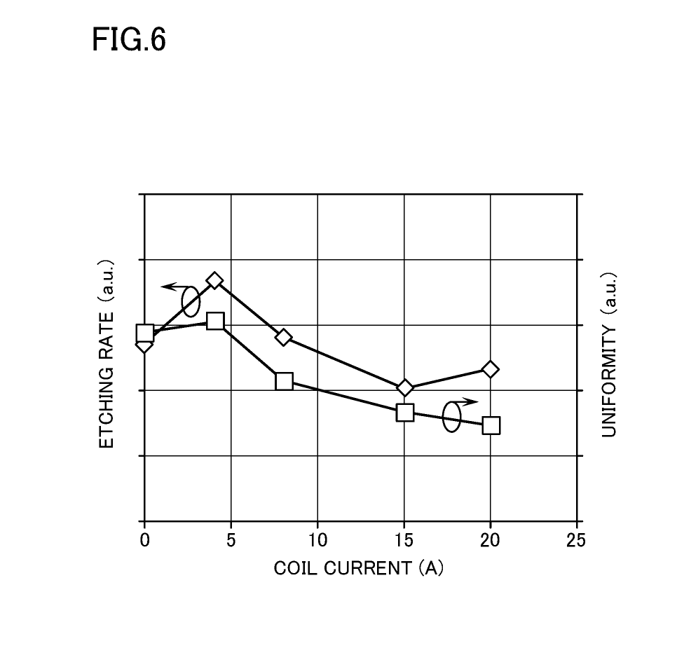

Then, by varying the electric currents to flow though the coil 9 on the above-mentioned etching conditions like 0 A, 4 A, 8 A, 15 A, 20 A, the etching rates were measured. The distance between the substrate W and the target 21 was set to be 600 mm, the distance between the substrate W and the coil 9d was set to be 82.5 mm, and the distance between the coil 9d and the coil 9u was set to be 86 mm. The results of measurements of the etching rates at this time are shown in FIG. 6. According to this arrangement, it has been confirmed that, as long as the electric current to the coil is set within a range of 5 A˜15 A, the in-plane uniformity of the etching rate can be improved.

### EXPLANATION OF REFERENCE MARKS

E1 first electric power
E2 second electric power
SM sputtering apparatus (film forming apparatus)
W substrate
1 vacuum chamber
4 stage
7c deposition prevention plate
7d deposition prevention plate (second deposition prevention plate)
71 that portion of the deposition prevention plates 7c which is proximate to the substrate (=such a portion of the deposition prevention plates 7c as is adjacent to the substrate)
72 projected strip
8 driving means
21 target
10 second driving means

1. A film forming apparatus comprising:
a vacuum chamber in which a target is disposed;
a stage for holding a substrate inside the vacuum chamber;
a first power source for applying a predetermined electric power to the target;
a second power source for applying AC power to the stage, thereby performing: film forming processing in which the target is sputtered by applying electric power by the first power source to the target; and etching processing in which a thin film formed on the substrate is etched by applying AC power by the second power source to the stage,
characterized in that the film forming apparatus has disposed a deposition prevention plate which encloses the stage,
let that side of the substrate held in position by the stage which is subjected to film forming be defined as an upper side, the film forming apparatus further comprises a driving means for moving up and down the deposition prevention plate between a film forming position in which that portion of the deposition prevention plate which is proximate to the substrate is positioned on a plane substantially equal to an upper surface of the substrate, and an etching position in which the said portion of the deposition prevention plate is positioned above the upper surface of the substrate.

2. The film forming apparatus according to claim 1, wherein a projected strip elongated downward is disposed in that portion of the deposition prevention plate which is proximate to the substrate.

3. The film forming apparatus according to claim 2, wherein a height of the projected strip is set to be equal to or above a distance between the film forming position and the etching position.

4. The film forming apparatus according to claim 2, wherein the height of the projected strip is set to a range of 10˜30 mm.

5. The film forming apparatus according to claim 1, further comprising: a second deposition prevention plate disposed below the deposition prevention plate; and a second driving means for moving up and down the second deposition prevention plate between a film forming position in which an upper end portion of the second deposition prevention plate is positioned below the substrate, and the etching position in which the upper end portion of the second deposition prevention plate, that has been moved to the etching position, is proximate to the substrate.

6. The film forming apparatus according to claim 1, wherein the vacuum chamber comprises a pair of upper and lower coils, and wherein the pair of upper and lower coils are positioned relative to the vacuum chamber so as to sandwich, in the vertical direction, plasma generated when AC power is applied to the stage by the second power source.

7. A film forming method comprising:
a film forming step in which a substrate is held by a stage in a vacuum chamber, a deposition prevention plate is disposed so as to enclose the stage, and a predetermined electric power is applied to a target in the vacuum chamber to thereby perform sputtering; and
an etching step in which the electric power application to the target is stopped, and AC power is applied to the stage to thereby etch a thin film formed on the substrate,
wherein, let that side of the substrate held by the stage which is the film-forming side be defined as an upper side, in the film forming step, the deposition prevention plate is moved to a film forming position in which that portion of the deposition prevention plate which is proximate to the substrate is positioned on a plane substantially equal to an upper surface of the substrate, and
wherein, in the etching step, the deposition prevention plate is moved to an etching position which is different from the film forming position and in which the said portion of the deposition prevention plate is positioned above the upper surface of the substrate.

8. The film forming method according to claim 7, wherein the etching position is positioned 10˜30 mm above the film forming position.

9. The film forming method according to claim 7, wherein,
in the film forming step, a second deposition prevention plate is disposed below the upper surface of the substrate,
in the etching step, the second deposition prevention plate is moved upward so that the particles scattered from the thin film can be prevented from passing through a clearance between that portion of the deposition prevention plate which is proximate to the substrate and the substrate, to thereby adhere to an inner surface of the vacuum chamber.
